(19) United States
(12) Patent Application Publication
(10) Pub. No.: US 2003/0161265 A1
(43) Pub. Date: Aug. 28, 2003

(54) System for end user monitoring of network service conditions across heterogeneous networks

(76) Inventors: Jingjun Cao, Mountain View, CA (US); Fujio Watanabe, San Jose, CA (US); Shoji Kurakake, San Francisco, CA (US)

Correspondence Address: BRINKS HOFER GILSON & LIONE, ONE INDIANA SQUARE, SUITE 1600, INDIANAPOLIS, IN, 46204-2033, US

(21) Appl. No.: 10/082,644

(22) Filed: Feb. 25, 2002

(51) Int. Cl. G01R 31/08; H04L 12/28

(52) U.S. Cl. 370/229; 370/401

(57) ABSTRACT

A network monitoring system for monitoring network performance across heterogeneous networks with an end device is disclosed. The network monitoring system includes a network comprising a first heterogeneous network communicatively coupled with a second heterogeneous network. The first heterogeneous network may include the end device, an intermediate node and a gateway. The second heterogeneous network may include an application server. The end device and the application server may communicate over the network with a datastream. The end device may generate a tracer packet as part of the datastream. The datastream may travel through the intermediate node. The intermediate node may store network service information in the tracer packet. The gateway may operate as an interface to the second heterogeneous network. The gateway may intercept the tracer packet and store network condition information therein. In addition, the gateway may redirect the tracer packet back to the end device over the first heterogeneous network. The end device may process the information contained in the tracer packet to determine current network and application server operating conditions, and provide results of the processing to a user of the end device.

### FIELD OF THE INVENTION

The present invention relates generally to network performance monitoring and more particularly, to methods and systems for end user monitoring of the performance of heterogeneous networks and network applications running thereon.

### BACKGROUND OF THE INVENTION

Wireless telecommunication networks are rapidly converging with wireline based networks to extend access to the Internet. One prevalent reason for this convergence may be due to improved utilization of available wireless network resources by packet switching when compared with circuit switching. Another reason may be to allow access via wireless networks to the large variety of data applications already available on the Internet.

Wireless networks, however, have fundamentally different characteristics from wireline-based networks. For example, wireless networks may experience higher error rates due to radio-based communications. In addition, mobile devices in wireless networks typically share available radio frequency bandwidth, such as, for example, by utilizing time division multiple access (TDMA). Further, wireless networks are typically capable of transferring an active communication channel among different base stations (described as “handover” in cellular technology) as the geographical position of a mobile device relative to different base stations changes.

In addition to the technical differences, wireless access to the Internet may also have significant business differences. In wireline networks, Internet service providers (ISPs) typically provide subscribers access to the Internet. The ISPs typically charge fees merely for connectivity to the Internet. Typically, wireline based ISPs provide some form of a quality of service guarantee to subscribers. Such service level agreements are usually specified in a statistical sense, such as, for example, guaranteeing wireline network down time to be no more than 1%.

Wireless service providers may similarly provide subscribers access to wireless networks using service agreements. In wireless networks however, wireless service providers may develop and deploy additional value added services to generate revenue. Such services may include different levels of service with controllable, or at least measurable, quality of the level of services provided. For example, wireless network subscribers may choose to purchase premium service for high grade, high bit rate data and voice transmission with some level of guaranteed quality and reliability of the service. Alternatively, an economic service for “best-effort” data and voice transmission may be chosen.

A significant problem for the subscribers of not only wireline-based Internet service providers, but also the subscribers of wireless service providers, is the ability to monitor for compliance with such a service agreement. With the advent of the Internet and various networking standards and technologies, there have been a great number of network monitoring technologies, products, and services. For example, Internet control message protocol (ICMP) is a simple IP network protocol providing limited error messages to the transmitting node. In general, if a router in the network drops an IP packet, the router will generate an ICMP packet and send it to the node that originated the lost packet. This monitoring technology, however, provides only limited information. In addition, error messages are only generated when IP packets are dropped.

Network management software packages are available that may include more sophisticated forms of monitoring. Typically such network management software packages are designed for private network management, such as, for example, local area network (LAN) management. As such, the packages are developed for a network administrator/owner to manage overall network activity. A typical architecture deploys software agents to each of a plurality of local network nodes such as, for example, routers, servers and workstations. The agents monitor node performance and periodically provide performance data to a central network management station. The network management station may then present aggregate data to the network administrator. Within these systems, the information gathered is rarely useful to individual workstations. In addition, getting such information to individual workstation may be inefficient and cumbersome.

Technologies with instant and dynamic network service monitoring capabilities are currently unavailable for individual subscribers of wireless and wireline networks. These subscribers have no way of identifying the source of network communication problems and therefore cannot react appropriately when such problems occur. For example, if a subscriber is in the process of downloading a large file and data transfer slows and/or stops, there is little information available for the subscriber to use in determining whether he should wait, abort and reinitiate the download, or complain to the service provider. There is no information available for the user to conveniently determine whether such problems are a result of the ISP access network, Internet traffic congestion in the backbone, and/or performance of the application server. In addition, wireless network subscribers have additional variables related to those characteristics previously identified as unique to wireless networks. These subscribers currently have no way of determining if such a condition is caused by handover between base stations, lack of coverage area, and/or a wireless network providers failure to provide the level of services purchased by the subscriber.

### SUMMARY OF THE PRESENT INVENTION

The presently preferred embodiments disclose a network monitoring system that may be used by a user operating an end device. The network monitoring system may monitor network-operating conditions of heterogeneous networks as well as devices/applications within those networks. The system is drastically different from conventional network management technologies, where a centralized network monitoring station gathers information from network monitoring agents deployed at various network nodes. In the network monitoring system, when the end device is communicating with a destination device over heterogeneous networks to run a network application, the end device may initiate network probing. Network probing may dynamically provide almost instantaneous network operating conditions to the end device. The end device may display the results of such probing for the benefit of the user operating the end device. The resulting performance related information may be useful to the user in ascertaining the source of network communication issues and problems.

A network architecture may include any number of access networks. In an illustrative embodiment, the network architecture includes a first heterogeneous network and a second heterogeneous network communicatively coupled, preferably via the core Internet. Each of the heterogeneous networks may include at least one intermediate node such as, for example, a router or access point. In this embodiment, at least one end device operating within the first heterogeneous network may communicate with a destination device, such as, for example, an application server operating in the second heterogeneous network. At least one gateway within the first heterogeneous network provides an interface with other heterogeneous networks, which may include the core Internet. Accordingly, datastreams may be communicated via the intermediate nodes and the gateway between the end device and the destination device.

In the presently preferred embodiments, the network monitoring system includes an end device network monitoring module (NMM) operating on each end device and a gateway NMM operating on each gateway. In addition, intermediate node NMMs may operate on some, or all, of the intermediate nodes. Each intermediate node NMM may monitor and store network performance conditions related to the intermediate node on which it operates. Similarly, the gateway NMMs may monitor and store network performance conditions related to the respective gateway. In addition, the gateway NMMs may store probing information gathered from the destination devices communicating with the end devices.

To initiate monitoring of network operating conditions, an end device may selectively send a tracer packet over the first heterogeneous network in a datastream with packets containing application data. The tracer packet may include a source address of the end device and a destination address of the destination device. Those intermediate nodes that include intermediate node NMMs, and gateways that include gateway NMMs, may recognize and process tracer packets traveling therethrough.

Processing by the intermediate node NMMs may involve writing the stored network performance conditions into the tracer packets.

The gateway NMMs may process tracer packets by utilizing the destination addresses to gather probing information for the corresponding destination devices. The probing information together with the network performance conditions related to the gateways may be written into tracer packets as network condition information. The gateway NMMs may also interchange the source address and the destination address to re-route tracer packets back through the first heterogeneous network to the end device. When the tracer packets travel back to respective end devices, respective end device NMMs operating therein may decipher the information accumulated in the respective tracer packets and present it to the respective users of the end devices.

An interesting feature of the network monitoring system involves the relatively small increase in traffic over the network architecture due to network monitoring activities. The tracer packets may be generated manually, automatically based on a schedule and/or automatically based on operating conditions. Accordingly, relatively few tracer packets are selectively generated on an as needed basis to perform network service probing.

Another interesting feature of the network monitoring system relates to characteristics of the tracer packets. The tracer packets are designed to accommodate variable sized data with a flexible format that allows changes to the format or content of the tracer packet without significant design changes to the network monitoring system. In addition, changes to the tracer packets do not affect the operation and stability of datastreams within the network. Further, tracer packets may be treated similarly to other packets in the datastream where the network monitoring system is not present.

Yet another interesting feature involves deployment of the network monitoring system in a heterogeneous network. Once an end device in the heterogeneous network includes an end device NMM and each of the gateways in the heterogeneous network include a gateway NMM, the network monitoring system is operational. Accordingly, deployment of additional end device NMMs and intermediate node NMMs may be incremental without operational interruption or detrimental impact to the network monitoring system. Further, the network monitoring system may be deployed within a single heterogeneous network while providing monitoring that encompasses performance of other heterogeneous networks and associated devices.

Still another interesting feature of the network monitoring system is related to scalability. Although tracer packets are sent selectively, statistical information for extended periods of time may be provided in the tracer packets due to the ongoing accumulation of network performance information at the intermediate nodes and gateways. As such, the network monitoring system imposes minimal overhead traffic while still providing almost constant monitoring.

Further objects and advantages of the present invention will be apparent from the following description, reference being made to the accompanying drawings wherein preferred embodiments of the present invention are clearly shown.

### BRIEF DESCRIPTION OF THE DRAWINGS

FIG. 1 is a block diagram of a network architecture that includes an embodiment of a network monitoring system.

FIG. 2 is a block diagram of one embodiment of a high-level system architecture for the network monitoring system illustrated in FIG. 1.

FIG. 3 is a block diagram of one embodiment of an end device network-monitoring module operating in the network monitoring system illustrated in FIG. 1.

FIG. 4 is a block diagram illustrating the format of one embodiment of a tracer packet generated by the end device network-monitoring module depicted in FIG. 3.

FIG. 5 is a flow diagram illustrating operation in a plurality of probing modes of the end device network-monitoring module illustrated in FIG. 3.

FIG. 6 is a flow diagram illustrating operation of one embodiment of the end device network-monitoring module depicted in FIG. 3.

FIG. 7 is second portion of the flow diagram illustrated in FIG. 6.

FIG. 8 is a block diagram of one embodiment of an intermediate node network-monitoring module operating in the network monitoring system illustrated in FIG. 1.

FIG. 9 is a block diagram of one embodiment of a gateway network-monitoring module operating in the network monitoring system illustrated in FIG. 1.

FIG. 10 is a more detailed block diagram of one embodiment of a portion of the gateway network-monitoring module illustrated in FIG. 9.

FIG. 11 is a flow diagram illustrating operation of one embodiment of the intermediate node network-monitoring module and the gateway network-monitoring module depicted in FIGS. 8, 9 and 10.

FIG. 12 is second portion of the flow diagram illustrated in FIG. 11.

### DETAILED DESCRIPTION OF THE PREFERRED EMBODIMENTS

The presently preferred embodiments describe a network monitoring system for monitoring network performance of heterogeneous networks. The network monitoring system may efficiently solve network service monitoring challenges for users operating end devices in one of the heterogeneous networks. Such an individual may perform network service probing to determine operating conditions within the heterogeneous networks.

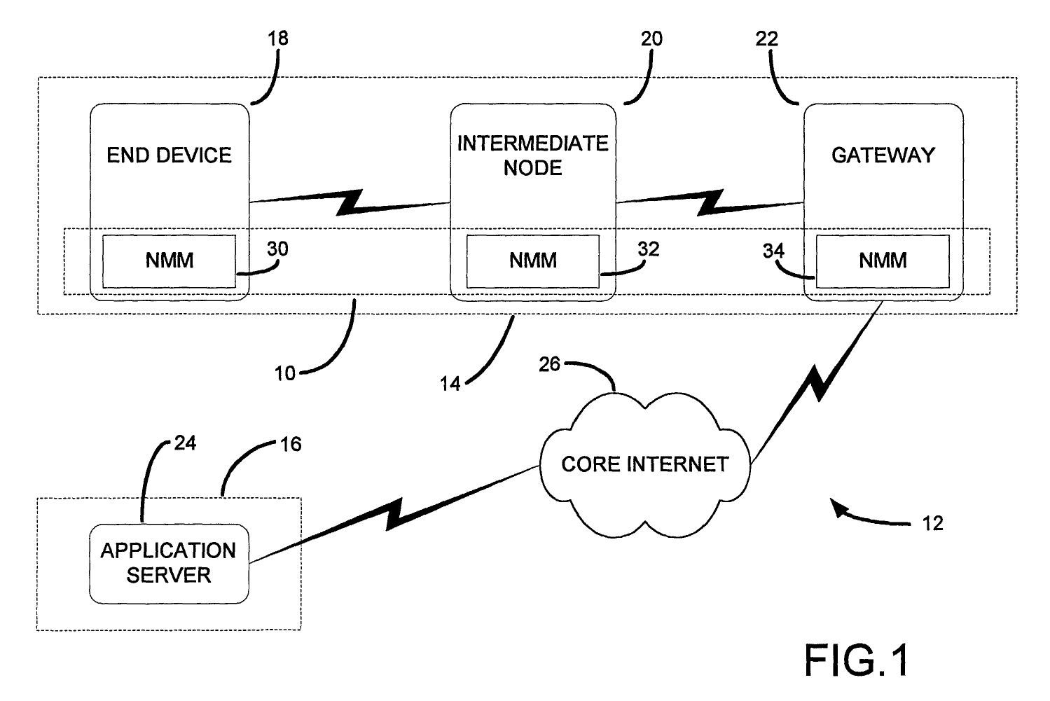

FIG. 1 is a block diagram of one embodiment of a network monitoring system 10 operating within a network architecture 12. The network architecture 12 may include any number of access networks illustratively depicted in FIG. 1 as a first heterogeneous network 14 communicatively coupled with a second heterogeneous network 16. The first heterogeneous network 14 includes at least one end device 18, at least one intermediate node 20 and at least one gateway 22 operative coupled as illustrated. The second heterogeneous network 16 includes at least one application server 24. The first and second heterogeneous networks 14, 16 in the illustrated embodiment are interconnected via the core Internet 26. In other embodiments, the first and second heterogeneous networks 14, 16 may be directly coupled, interconnected through one or more heterogeneous networks, and/or any other form of interconnection allowing communication between the first and second heterogeneous networks 14, 16. As used herein, the term “coupled”, “connected”, or “interconnected” may mean electrically coupled, optically coupled or any other form of coupling providing an interface between systems, devices and/or components.

The network architecture 12 may include any number of networks in a hierarchal configuration such as, for example, the Internet, public or private intranets, extranets, and/or any other forms of network configuration to enable transfer of data and commands. Accordingly, the network architecture 12 is not limited to the core Internet 26 and the first and second heterogeneous networks 14, 16 illustrated in FIG. 1. As referred to herein, the network architecture 12 should be broadly construed to include any software application and hardware devices used to provide interconnected communication between devices and applications. For example, interconnection with the core Internet 26 may involve connection with an Internet service provider using, for example, modems, cable modems, integrated services digital network (ISDN) connections and devices, digital subscriber line (DSL) connections and devices, fiber optic connections and devices, satellite connections and devices, wireless connections and devices, Bluetooth connections and devices, or any other communication interface device. Similarly, intranets and extranets may include interconnections via software applications and various computing devices (network cards, cables, hubs, routers, etc.) that are used to interconnect various computing devices and provide a communication path.

The network architecture 12 of the presently preferred embodiment is a packet-switched communication network. An exemplary communication protocol for the network architecture 12 is the Transport Control Protocol/Internet Protocol (“TCP/IP”) network protocol suite, however, other Internet Protocol based networks, proprietary protocols, or any other form of network protocols are possible. Communications may also include, for example, IP tunneling protocols such as those that allow virtual private networks coupling multiple intranets or extranets together via the Internet. The network architecture 12 may support protocols, such as, for example, Telnet, POP3, Multipurpose Internet mail extension (MIME), secure HTTP (S-HTTP), point-to-point protocol (PPP), simple mail transfer protocol (SMTP), proprietary protocols, or any other network protocols known in the art.

In the illustrated embodiment, the first and second heterogeneous networks 14, 16 may include public and/or private intranets, extranets, local area networks (LAN) and/or any other forms of network configuration to enable transfer of data and commands. Communication within the first and second heterogeneous networks 14, 16 may be performed with a communication medium that includes wireline based communication systems and/or wireless based communication systems. The communication medium may be for example, a communication channel, radio waves, microwave, wire transmissions, fiber optic transmissions, or any other communication medium capable of transmitting data, audio and/or video. In the presently preferred embodiments, the first heterogeneous network 14 is a wireless access network, such as, for example, a cellular network an 802.11b wireless LAN, a Bluetooth network, a Home Radio Frequency (HomeRF) network or any other type of wireless network. The second heterogeneous network is any other type of access network. In other embodiments, the first heterogeneous network 14 may also be any other type of access network.

The end device 18 may be any device acting as a source of data packets and a destination for data packets transmitted in a datastream over the network architecture 12. As used herein, the terms “packets,” “data packets” or “datagrams” refers to transmission protocol information as well as data, video, audio or any other form of information that may be transmitted over the network architecture 12. In the presently preferred embodiments, the end device 18 is a wireless device such as, for example, a personal digital assistant (PDA), a wireless phone, a notebook computer or any other wireless mobile device utilized by an end user to interface with the network architecture 12. The terms “end user” and “user” represents an operator of an end device 18.

Interface of the end device 18 with the network architecture 12 may be provided with an access network. The access network for the end device 18 in the illustrated embodiment is the first heterogeneous network 14. Where the end device 18 is a wireless device, the access network may include access points, such as, for example, base stations acting as intermediate nodes 20 to provide radio communication with the end device 18 as well as communication with the rest of the network architecture 12.

The end device 18 may include a user interface (UI) such as, for example, a graphical user interface (GUI), buttons, voice recognition, touch screens or any other mechanism allowing interaction between the end user and the end device 18. In addition, the end device 18 may include a processor, memory, a data storage mechanism and any other hardware to launch and run applications.

Applications may include software, firmware or some other form of computer code. In the presently preferred embodiments, the end device 18 includes an operating system and applications capable of communicating with remote applications operating elsewhere in the network architecture 12. For example, an end user may activate an end device 18 such as a wireless phone. When the wireless phone is activated, an application is launched to provide the functions available from the wireless phone such as dialing and receiving phones calls. In addition, the user may initiate other applications to communicate with remote application services located elsewhere in the network architecture 12, such as, for example, interactive messaging, an Internet browser, email services, stock market information services, music services, video on demand services and the like. Packets transmitted and received by the end device 18 over the network architecture 12 may travel through the intermediate node 20 and the gateway 22 within the first heterogeneous network 14.

As illustrated in FIG. 1, the end device 18 may include a portion of the network monitoring system 10 that is as an end device network-monitoring module (NMM) 30. The end device NMM 30 may generate a tracer packet to probe conditions within the network architecture 12. The probing of network operating conditions may be initiated from the end device 18 using one or more tracer packets. The tracer packets may be selectively inserted into the datastream with other packets sent over the first heterogeneous network 14. As described later, the tracer packets may perform network service probing to collect network-operating condition information before returning to the end device 18. In general, network service probing provides information related to operational performance of devices and systems within the network architecture 12. The end device NMM 30 may extract the information from the tracer packets and provide such information to the user.

The intermediate node 20 may be any form of datastream processing location within the first heterogeneous network 14. In the presently preferred embodiments, the intermediate node 20 is a packet transfer device, such as, for example, a router and/or an access point within the first heterogeneous network 14. The intermediate node 20 may receive packets and forward such packets toward a destination identified in the packets. Each intermediate node 20 includes a unique identifier such as, for example a network address. With the unique identifier, the intermediate node 20 may forward packets from one intermediate node 20 to another based on the identified destination to form one of a series of “hops” between the source and the destination. The intermediate node 20 may include a processor, memory, a data storage mechanism and any other hardware and applications to perform an access and/or packet forwarding function within the first heterogeneous network 14.

As further illustrated in FIG. 1, the intermediate node 20 may include a portion of the network monitoring system 10 that is an intermediate node NMM 32. As described later in detail, the intermediate node NMM 32 is capable of writing network service information into tracer packets traveling through the intermediate node 20. The network service information includes information on network traffic conditions, such as, for example, congestion and delay with regard to the intermediate node 20.

The gateway 22 may be any device or mechanism capable of forming a communication interface to other heterogeneous or non-heterogeneous networks. In the illustrated embodiment, the gateway 22 operates in the first heterogeneous network 14 to provide an interface via the core Internet 26 to other heterogeneous networks. In other embodiments, the gateway 22 may operate at the edge of any network as a communication interface to one or more other networks and may, or may not, include communication over the core Internet 26. The gateway 22 operates in a well-known manner to perform, for example, routing, proxying, caching, etc. for packets passing between the first heterogeneous network 14 and other networks and/or the core Internet 26. The gateway 22 may include a processor, memory, a data storage mechanism and any other hardware and applications to maintain the link between the first heterogeneous network 14 and other heterogeneous networks.

As further illustrated in FIG. 1, the gateway 22 may include a portion of the network monitoring system 10 that is a gateway NMM 34. The gateway NMM 34 may filter the datastream to extract tracer packets sent by the end device 18. Extracted tracer packets may be rerouted (or echoed) back to the end device 18 in the datastream. In addition, the gateway NMM 34 may store network condition information in the tracer packets.

Network condition information includes network service information for the gateway 22, as well as operational conditions outside the first heterogeneous network 14. Exemplary remote operating conditions include network service/loading information pertaining to a destination device to which communication from the end device 18 is directed, the condition of the core Internet link 28 and/or any other operationally related information regarding communication/interaction between the first heterogeneous network 14 and the destination device. In the illustrated embodiment, the destination device is the application server 24. In other embodiments, the destination device may be any other device or system within the network architecture 12.

The application server 24 may be any device(s) capable of serving applications over the network architecture 12. In the illustrated embodiment, the application server 24 is within the second heterogeneous network 16. In other embodiments, any number of application servers 24 may be located anywhere in the network architecture 12. The application server 24 may be one or more server computers operating in a well-known manner within the network architecture 12.

During operation of the embodiment illustrated in FIG. 1, when a user is operating the end device 18 to access a remote application running on the application server 24, packets forming a datastream are transmitted over the network architecture 12. The datastream may flow through the intermediate node 20 and the gateway 22 in the first heterogeneous network 14. In addition, the datastream may flow through the core Internet 26 and the second heterogeneous network 16.

Within the datastream generated by the end device 18, the end device NMM 30 may selectively include a tracer packet. The intermediate node NMM 32 within intermediate node(s) 20 through which the tracer packet passes may store network service information in the tracer packet. The gateway NMM 34 operating in the gateway 22 may filter the datastream passing therethrough to capture and extract the tracer packet. The gateway NMM 34 may store network condition information and echo the tracer packet back to the end device 18 through the intermediate note(s) 20. At the end device 18, the end device NMM 30 may interpret the information stored in the tracer packet and provide the results to the end user operating the end device 18.

The network monitoring system 10 enables a user utilizing the end device 18 and a remote application over the network architecture 12 to probe the condition of the network architecture 12. This probing ability is especially helpful to the user when the application may be experiencing network related problems. For example, if a user who is a wireless network subscriber in the process of downloading a multimedia file with the end device 18 experiences slow and/or stopped data transfer, it would be beneficial for the user to know why. If the problem was a wireless service provider problem such as, for example, an overcrowded base station or a communication channel that was dropped, the user may have a level of service complaint. If, however, the remote application server providing the multimedia file was creating the problem, the user's reaction to the problem may be different.

Another example is a user who is a wireless network subscriber using video conferencing services for an important business meeting while driving a vehicle. Such a user may pay for premium wireless service and naturally wants the best service quality. If the service quality degrades, such a user would like to know whether the degradation was due to reaching the edge of the wireless coverage area or if a handover is occurring and the wireless service will soon recover. In the first case the user may decide to pull the vehicle over and finish the conference, while in the second case continuing to travel may allow entry into an area with better coverage.

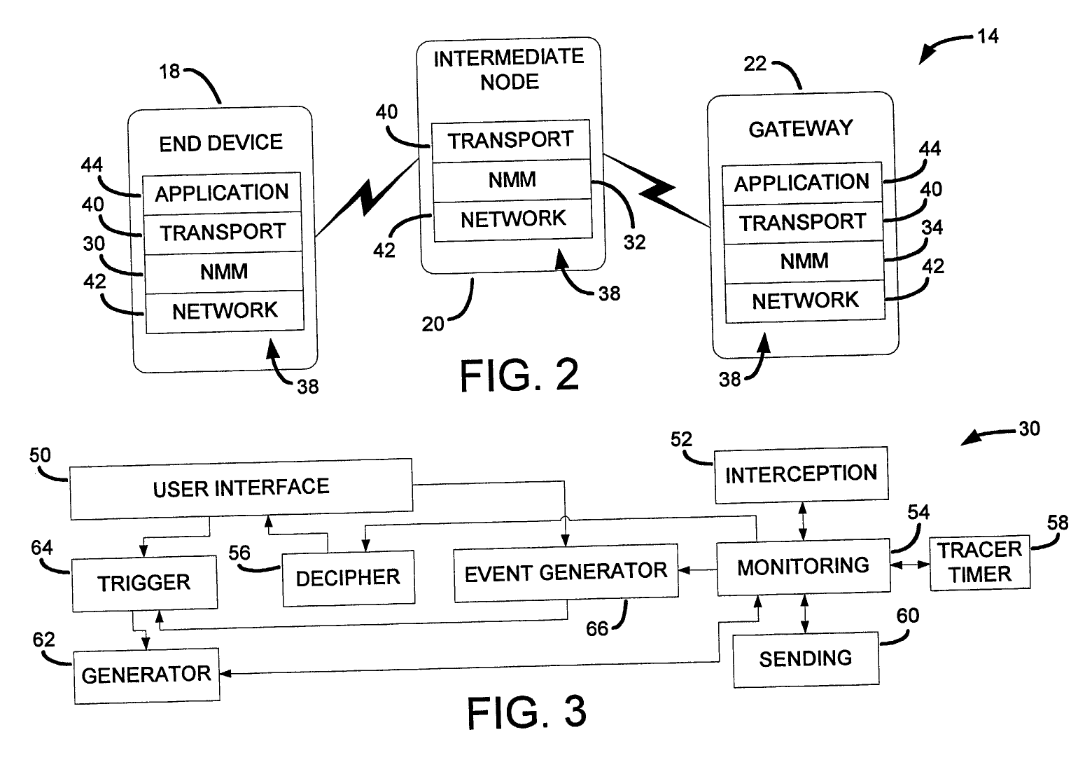

FIG. 2 is a block diagram of one embodiment of a high-level system architecture of the network monitoring system 10 (FIG. 1) operating within the devices of the first heterogeneous network 14. As previously discussed, the network monitoring system may include at least one end device NMM 30, at least one intermediate node NMM 32 and at least one gateway NMM 34.

As known in the art, an open system interconnection (OSI) seven-layer model provides an abstract model of networking in which a networking system may be divided into layers. In the illustrated embodiment, each of the end device 18, the intermediate node 20 and the gateway 22 include a network protocol stack 38 to illustrate the relevant portions of the networking architecture therein. The end device 18 includes the end device NMM 30 operating between a transport layer 40 (the transport layer (L4) of the OSI model) and a network layer 42 (the network layer (L3) of the OSI model). In one embodiment, a transmission control protocol/user datagram protocol (TCP/UDP) is associated with the transport layer 40 and an Internet protocol (IP) is associated with the network layer 42. In addition, applications may operate within the end device 18 in an application layer 44 (the application layer (L7) of the OSI model).

The end device NMM 30 may monitor network communication by an application(s) operating in the application layer 44 within the end device 18. In addition, information may be gathered by the end device NMM 30 about any other layer of the OSI model, such as, for example, the physical layer (L1), the data link layer (L2), the network layer (L3), the transport layer (L4), the session layer (L5) and/or the presentation layer (L6).

As further illustrated in FIG. 2, the intermediate node NMM 32 operating on the intermediate node 20 may similarly operate between the transport layer 40 and the network layer 42. As such, the intermediate node NNM 32 may monitor the routing/access activities of the intermediate node 20 and gather information from any layer of the OSI model. The gateway NMM 34 may similarly operate between the transport layer 40 and the network layer 42. In addition, proxy/caching and other similar functionality performed by the gateway 22 may operate in the application layer 44. Accordingly, the gateway NMM 34 may probe any layer of the OSI model to gather the operational performance of the gateway 22 as well as performance characteristics related to interfacing with the remainder of the network architecture 12 (FIG. 1).

Referring now to FIGS. 1 and 2, with the presently preferred embodiments, the transport mechanism utilized by the network monitoring system 10 to probe devices within the network architecture 12 operates within the network layer 42. Accordingly, the heterogeneity of different access networks, such as the first heterogeneous network 14, may be accommodated while leaving sufficient design flexibility to monitor conditions specific to each particular access network. In addition, probing within the access networks may be selectively performed through selective deployment of the intermediate node NMMs 32 among intermediate nodes 20 within an access network. As such, when at least one end device NMM 30 and the gateway NMM(s) 34 are deployed and functional within an access network, gradual deployment to intermediate nodes 20 may occur while the network monitoring system 10 remains operational. Further, network service probing is available beyond the access network in which the network monitoring system is deployed.

While the transport mechanism for communication over the network architecture 12 is implemented at the network layer 42, the network service information reported by an intermediate node NMM 32 and/or a gateway node NMM 34 may be gathered from any layer of the OSI model. Accordingly, the network monitoring system 10 provides a simple yet universal tool for access network service monitoring. For example, an intermediate node 20 that is an access point of a wireless LAN may detect radio interference from an invading radio source, such as another access point. Such interference may be reported to the end device 18 as part of the network service information by the intermediate node NMM 32 operating on the access point. In another example of a wireless access network an intermediate node 20 operating as a base station of a cellular network may be crowded by too many concurrent users. The intermediate node NMM 32 operating on the base station may inform a probing end device 18 of the over-crowded condition via network service information.

The multiple layer (e.g. non-network layer) network service information may be reported to an end device 18 (FIG. 1) with flexibility and convenience. In one embodiment, each of the intermediate node NMMs 32 and the gateway NMMs 34 may encode network service information and network condition information, respectively, utilizing extensible markup language (XML). As such, the end device 18, may utilize a well-known XML parser to interpret the encoded information.

FIG. 3 is a block diagram illustrating the components of one embodiment of the end device Network Monitoring Module (NMM) 30 operating on the end device 18 (FIG. 1). The end device NMM 30 includes a User Interface component (UIC) 50, an end device packet Interception component (IC) 52, a traffic Monitoring component (MC) 54, a packet Decipher component (DC) 56, a Tracer Timer component (TTC) 58, a packet Sending component (SC) 60, a packet Generator component (GC) 62, a probing Trigger component (TC) 64 and an Event Generator component (EGC) 66. In other embodiments, additional or fewer components may be identified to describe the functionality of the end device NMM 30.

In still other embodiments, a portion of the end device NMM 30 may operate in the end device 18 and another portion of the end device NMM 30 may operate elsewhere in the first heterogeneous network 14 and/or the network architecture 12. For example, tracer packets may be generated elsewhere at the direction of the portion of the end device NMM 30 in the end device 18. After traveling through the first heterogeneous network 14, the tracer packets may return to the portion of the end device NMM 30 operating in the end device 18 for processing.

Referring now to FIGS. 1 and 3, the User Interface component 50 may cooperatively operate with the user interface of the end device 18 to present the results of network service probing to the user. In addition, the User Interface component 50 may allow a user to direct the operation of the end device NMM 30 via the user interface (UI). Further, settings such as, for example, a probing mode, time out intervals or any other parameters and/or settings related to probing the network monitoring system 10 may be configured utilizing the user interface component 50.

The end device packet Interception component 52 may be inserted below the transport layer 40 in the network protocol stack 38 as previously discussed with reference to FIG. 2. The end device packet Interception component 52 may intercept datastream traffic between the first heterogeneous network 14 and applications operating on the end device 18. In the illustrated embodiment, the end device packet Interception component 52 may pass datastreams to the traffic Monitoring component 54.

The traffic Monitoring component 54 may monitor the traffic flow. Monitoring the traffic flow involves keeping track of information such as, for example, application processes within the end device 18 incurring network traffic, realized bandwidth variation and/or any other information related to traffic flow between the end device 18 and the first heterogeneous network 14. The traffic Monitoring component 54 may monitor for tracer packets in the incoming traffic flow from the first heterogeneous network 14. Upon recognition of incoming tracer packets, the traffic Monitoring component 54 may pass such tracer packets to the packet Decipher component 56.

The packet Decipher component 56 may extract network service information stored by the intermediate node NMM 32, as well as network condition information stored by the gateway NMM 34 from the tracer packets. In addition, the packet Decipher component 56 may utilize the extracted information to compile the results of the network service probing. The network service probing results may then be forwarded to the User Interface component 50. The User Interface component 50 of one embodiment may display the results in the form of a graph or chart upon a GUI of the end device 18.

In addition to processing incoming datastreams, the traffic Monitoring component 54 may also process outgoing datastreams. Outgoing datastreams may include packets of application data generated by applications operating in the end device 18 as well as tracer packets. The traffic Monitoring component 54 may receive the packets of application data and mix outgoing tracer packets therewith to include in the outgoing datastream. Prior to mixing, the outgoing tracer packets may be registered by the traffic Monitoring component 54 with the Tracer Timer component 58.

The Tracer Timer component 58 may maintain a sending time for each outgoing tracer packet. Using the sending times, when a tracer packet sent by the end device 18 is lost in the network architecture 12, the Tracer Timer component 58 may reach a time out limit and inform the traffic Monitoring component 54. The time out limit of one embodiment is a predetermined time period. In another embodiment, the time out limit may be dynamically determined based on network conditions, end device 18 operating conditions or any other parameters. Timing by the Tracer Timer component 58 may be suspended by the traffic Monitoring component 54 upon receipt of the incoming tracer packet from the first heterogeneous network 14.

The outgoing datastream that includes the packets of application data and the tracer packets may be passed by the traffic Monitoring component 54 to the packet Sending component 60. The packet Sending component 60 may inject the outgoing datastream into the first heterogeneous network 14. The packet Sending component 60 may also receive and forward incoming datastreams to the packet Monitoring component 54. In one embodiment, the packet Sending component 60 may forward the outgoing datastreams to the network layer 42 (FIG. 2) positioned below the end device NMM 30 in the network protocol stack 38 (FIG. 2). In addition, the packet Sending component 60 of this embodiment may receive incoming datastreams from the network layer 42 (FIG. 2).

Tracer packets may be generated by the packet Generator component 62. Once enabled, the packet Generator component 62 determines what to probe and generates a tracer packet corresponding thereto. The determination of what to probe involves calling the traffic Monitoring component 54 to identify a destination. The destination may be any device or system within the network architecture 12 that network service probing is directed toward. For example, in the embodiment illustrated in FIG. 1, the destination may be the application server 24.

The tracer packets generated by the packet Generator component 62 are specialized packets capable of traveling through the network architecture 12 as part of the datastream along with the packets of application data. Accordingly, the tracer packets may follow the same route as other data traffic and do not disrupt the stability of packet transportation through the network architecture 12. In addition, tracer packets may be treated similarly to any other packet in the datastream by intermediate nodes 20 which do not include the intermediate node NMM 32.

The tracer packets, however, include characteristics allowing identification of the tracer packets by the network monitoring system 10. In addition, the tracer packets may be capable of carrying variable amounts of data, a destination address identifying the destination and a source address identifying the end device 18 from which the tracer packet was generated. The destination address and source address may be any form of identifier that may be used within the network architecture 12 such as, for example, a Uniform Resource Identifier (URI), a name, a number or any other form of unique nomenclature. In the presently preferred embodiments, the destination address and source address are a destination IP address and a source IP address, respectively. The ability to carry variable amounts of data advantageously provides the flexibility to modify the format and/or the content of the tracer packets.

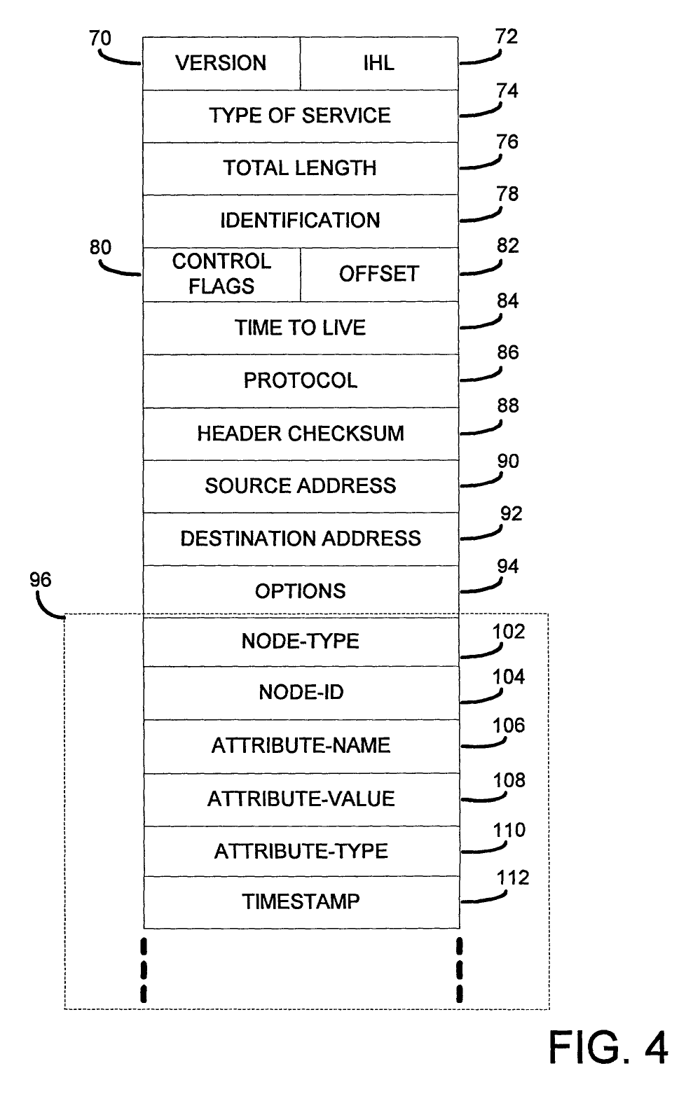

FIG. 4 is block diagram illustrating the format of one embodiment of a tracer packet generated by the packet Generator component 62. In this embodiment, the tracer packet uses the Internet header format of a well-known IP packet as defined by the Internet Protocol DARPA Internet Program Protocol Specification RFC 791 (September 1981). The illustrated tracer packet includes a version field 70, an Internet header length (IHL) field 72, a type of service field 74, a total length field 76, an identification field 78, a control flags field 80, an offset field 82 and a time to live field 84. In addition, the tracer packet includes a protocol field 86, a header checksum field 88, a source address field 90, a destination address field 92, an options field 94 and Heterogeneous Access Network Tracking (HANT) data 96.

Referring now to FIGS. 1 and 4, many of the illustrated fields of the tracer packet of this embodiment are populated with data similar in functionality to an application data IP packet. Accordingly, intermediate nodes 20 that do not include an intermediate node NMM 32 may treat the tracer packet as a regular data IP packet. For example, the source address field 90 of tracer packets generated by the packet Generator component 62 may be an IP address of the end device 18. In addition, the destination address field 92 may be, for example, an IP address of the application server 22. Accordingly, awareness of the structure and/or topology of the first heterogeneous network 14, as well as the rest of the network architecture 12, by the end device NMM 30 is unnecessary. Thus, implementation of the end device NMM 30 on the end device 18 may be straightforward. For purposes of brevity, the remainder of this discussion will focus on those aspects of the data contained in the tracer packets that is dissimilar in functionality from the functionality of data in typical application data IP packets.

The protocol field 86 of the tracer packet may be populated with a predetermined protocol value by the Generator component 62. As known in the art, assignments for existing IP protocol values, such as, for example, “6” for TCP, “1” for ICMP and “17” for UDP are described in the Assigned Numbers Specification—Network Working Group RFC 1700 (October 1994). The protocol value for the tracer packet may utilize any unassigned protocol value. In the presently preferred embodiments, unassigned protocol value “102” is chosen for the tracer packet protocol. In addition, the tracer packet protocol may be referred to as Heterogeneous Access Network Tracking (HANT) Protocol. The protocol value may be used by the network monitoring system 10 to identify tracer packets within the datastream.

The HANT data 96 is not part of the standard Internet header format of an IP-packet. It should be recognized, however, that the HANT data 96 may be added to a standard IP-packet without modification of standard packet switching datastream transmission. Further, the variable length feature of the HANT data 96 avoids instability of the transport system within the network architecture 12.

In one embodiment, the HANT data 96 of the tracer packet may be divided into eight-byte data segments. Each of the segments may be used to store network service information, or network condition information, supplied by the intermediate node NMMs 32 and the gateway NMM 34, respectively, as the tracer packet travels through the first heterogeneous network 14. Each attribute collected and stored in the tracer packets may be represented by one of the segments. Attributes may include, for example, congestion levels, delay levels or any other attributes pertaining to operational characteristics of the network architecture 12, the first heterogeneous network 14, the intermediate nodes 20, the gateways 22, the application server 24 or any other device(s) operating within the network architecture 12.

The format of each segment includes a node-type field 102, a node-id field 104, an attribute name field 106, an attribute value field 108, an attribute type field 110 and a timestamp field 112 as illustrated in FIG. 4. The node-type field 102 may describe the type of devices operating as intermediate nodes 20 or gateways 22 within the first heterogeneous network 14. For example, the node-type field 102 may indicate an intermediate node 20 is an access router. The node-id field 104 may provide a unique identifier assigned to intermediate nodes 20 and gateways 22 on which the network monitoring system 10 is operating. For example, the node-id may identify an intermediate node 20 as “ar3241.”

The attribute name field 106 may provide a description identifying the attribute included in the segment. For example, an attribute related to routing delay at an intermediate node 20 may have an attribute name of “routing delay.” The attribute value field 108 may be a numerical value, characters or some combination thereof that are descriptive of the current state of the attribute. For example, the attribute value field 108 associated with the attribute “routing delay” may include the term “high” or the number “30” in units of seconds to indicate the presence of a large delay. The attribute type field 110 may provide categories for grouping different attributes included in the network service information and the network condition information. The groupings may be utilized to provide results of network service probing representative of overall network operating conditions instead of operating conditions around a particular device. For example, the attribute name “routing delay” may be included in a category identified as “access network traffic characteristic” in the attribute type field 110 to characterize routing delay over the first heterogeneous network 14. The timestamp field 112 may include the time at which the attribute was stored in the tracer packet.

During operation, each intermediate node NMM 32 and gateway NMM 34 may add segments to the tracer packet for each attribute. As segments are added, the value in the total length field 76 may be modified accordingly. In one embodiment, where a tracer packet passes through an intermediate node 20 multiple times, new segments are added with each pass. In another embodiment, the intermediate node NMM 32 updates segments previously written to the tracer packets with the latest network service information.

The flexible packet length of the tracer packet provides for variable amounts of storage capability. As such, tracer packets may be utilized without regard to the number of intermediate nodes 20 and gateways 22 through which the tracer packets may travel. In addition, expansion of the network monitoring system 10 to additional intermediate nodes 20 and gateways 22 may accommodate future growth of the first heterogeneous network 14.

In another embodiment, the HANT data 96 of the tracer packet may be one variable length data segment. In this embodiment, information stored in the tracer packet may be appended to information previously stored therein. The appended information may be encoded in, for example, extensible markup language (XML). As such, modification of the variable data segment as well as processing techniques within the network monitoring system 10 may be performed, without modification to the tracer packet format.

Referring again to FIG. 3, the probing Trigger component 64 provides enablement of the packet Generator component 62. The probing Trigger component 64 may operate in conjunction with the packet Generator component 62 and the Event Generator component 66 to implement logic for determining when to generate and send a tracer packet.

The Event Generator component 66 may be a comparator of current network operating conditions with a stored threshold value. Upon exceedance of the threshold value, the Event Generator component 66 may generate a network problem signal for the probing Trigger component 64 to begin the process of generating tracer packets.

The logic implemented by the probing Trigger component 64 includes a plurality of probing modes to determine when network service probing should occur. Cooperative operation between the components is based on the probing mode selected.

In the presently preferred embodiments, there are three probing modes. The probing modes include a first mode that is an automatic probe mode, a second mode that is a manual probe mode and a third mode that is an event probe mode. In automatic probe mode, outgoing tracer packets may be produced periodically on a predetermined schedule. In manual probe mode, tracer packets may be produced upon user request. In event probe mode, tracer packets may be produced by the Event Generator component 66 based upon the occurrence of specified events. The trigger conditions associated with each of the probing modes may be controlled and/or configured by the end user. In addition, the end user operating the end device 18 (FIG. 1) may also perform selection of the probing mode. Within each probing mode of one embodiment, the end user may interrupt existing network service probing, and select a different probing mode.

Within the automatic probe mode of one embodiment, the traffic Monitoring component 54 may periodically monitor the network traffic and initiate generation and deployment of tracer packets on a predetermined schedule. The predetermined schedule may be a time interval, a 24-hour schedule, a monthly schedule or any other form of time based scheduling technique. In one embodiment, the predetermined schedule may be automatically adjusted based on network operating conditions. In this embodiment, the logical operation of the automatic probe mode may be further refined through considering accumulated historical information. For example, if traffic within the network architecture 12 (FIG. 1) is moderate, the time interval between deployment of tracer packets may be increased. If, however, traffic within the network architecture 12 becomes congested, the time interval between network service probing may be shortened to monitor more closely. The time interval may be any duration from seconds, to minutes, to hours depending on end user preferences. Accordingly, additional traffic generated by network service probing may be configured to have minimal effect on overall traffic volume in the network architecture 12.

The manual probe mode of one embodiment is enabled only when the end user invokes network service probing. Network service probing in the manual probe mode may be invoked by, for example, clicking on a “network probe” icon or any other mechanism for manually requesting initiation of the network service probing process. Once invoked, at least one tracer packet may be generated and deployed. Manual initiation of network service probing may occur, for example, when the end user notices changes in network performance and desires information on network operating conditions.

In event probe mode of one embodiment, the traffic Monitoring component 54 may continuously monitor network traffic for conditions warranting network service probing. Such conditions may include, for example, an abundance of lost packets, quality of packets sent, network traffic above some threshold magnitude, the quantity of application(s) operating on the end device 18 and/or any other trigger conditions that may occur with regard to communication over the network architecture 12. In the presently preferred embodiments, the traffic Monitoring component 54 monitors for sudden changes in network traffic characteristics. Sudden changes may include, for example, sudden decrease in bandwidth, increases in transmission delay or any other operational characteristics of the network architecture 12. Upon identification of sudden changes, the traffic Monitoring component 54 may notify the Event Generator component 66, which will generate an event. The event may enable the probing Trigger component 64 to trigger generation of at least one tracer packet by the packet Generator component 62. In one embodiment, the nature of the event may be used to determine the number of tracer packets generated and deployed.

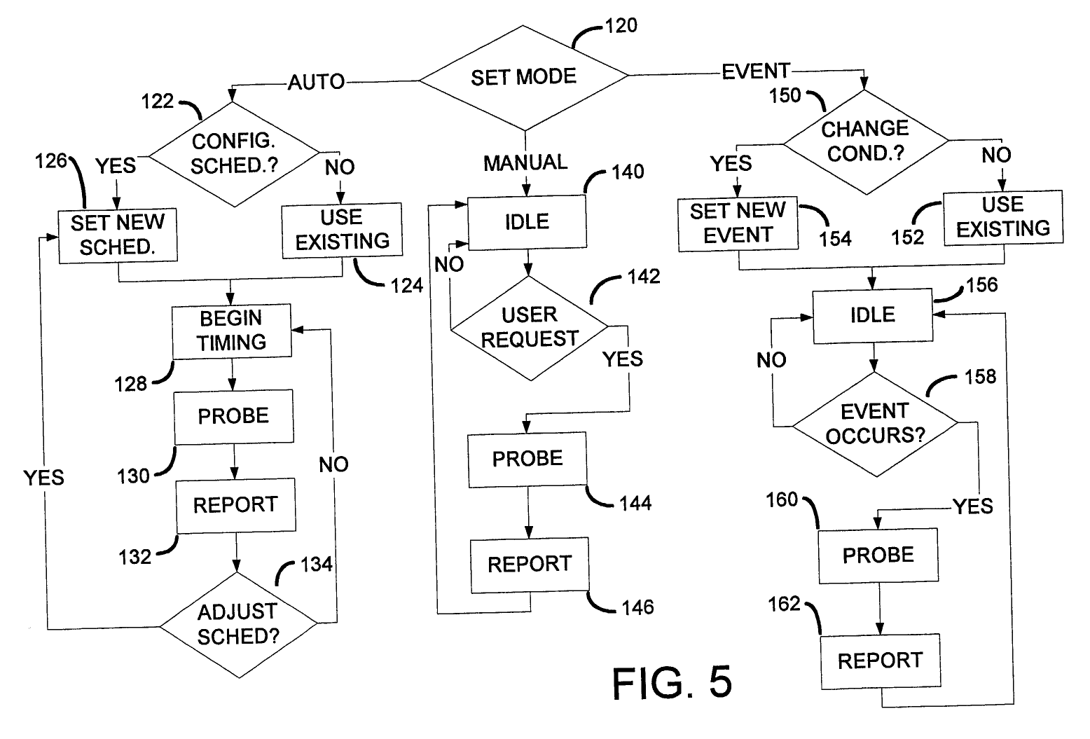

FIG. 5 is a process flow diagram illustrating logical operation of the probing modes of the presently preferred embodiments. Referring to FIGS. 1, 3 and 5, the operation begins at block 120 where an end user operating an end device 18 sets the probing mode as one of automatic probe mode, manual probe mode and event probe mode.

When automatic probe mode is selected, the end user is prompted to configure the predetermined schedule at block 122. If the end user elects not to configure the schedule, an existing schedule is used at block 124. If the end user elects to configure a schedule, the end user is prompted to configure the schedule at block 126. At block 128, the operation implements the current predetermined schedule and begins timing. When the predetermined time is reached, the probing Trigger component 64 initiates network service probing at block 130. At block 132, the network service probing is complete and a report is generated at the end device 18 for the end user. The end user may elect to adjust the predetermined schedule at block 134. If the end user elects to adjust the schedule, the operation returns to block 126. If the end user elects not to adjust the schedule, the operation returns to block 128 and continues timing with the existing schedule.

When the end user selects manual probe mode at block 120, the operation reverts to an idling state at block 140. At block 142, the operation checks for a user request to perform network service probing. If there is no request, the operation returns to block 140 and continues idling. If a request is made, the probing Trigger component 64 initiates network service probing at block 144. At block 146, the network service probing is complete and a report is generated at the end device 18 for the end user. The operation then returns to block 140 and repeats.

If the end user selects event probe mode at block 120, the end user is prompted to modify the conditions triggering network service probing at block 150. If the user elects not to change the trigger conditions, the existing conditions are used at block 152. If the user elects to change the trigger conditions, new/different conditions may be set at block 154. At block 156, the operation enters an idle mode in which the current trigger conditions are implemented. The operation monitors for occurrence of an event identified in the trigger conditions at block 158. If such an event does not occur, the operation returns to block 156 and continues idling. If an event including the trigger conditions occurs, the traffic Monitoring component 54 enables the probing Trigger component 64 to initiate network service probing at block 160. At block 162, the network service probing is complete and a report is generated at the end device 18 for the end user. The operation then returns to block 156 and repeats.

Referring again to FIG. 3, the traffic Monitoring component 54 in conjunction with the Tracer Timer component 58 may initiate the generation of a dummy tracer packet when an outgoing tracer packet fails to return within the time out limit. The dummy tracer packet is configured similarly to the outgoing tracer packet by the packet Generator component 62 and includes indication that the outgoing tracer packet was lost. The dummy tracer packet may be generated and passed to the traffic Monitoring component 54. The traffic Monitoring component 54 may pass the dummy tracer packet to the packet Deciphering component 56 for processing as previously described. The packet Decipher component 56 may interpret the tracer packet and provide results indicating, for example, that radio contact with the intermediate node 20 (an access point) is lost.

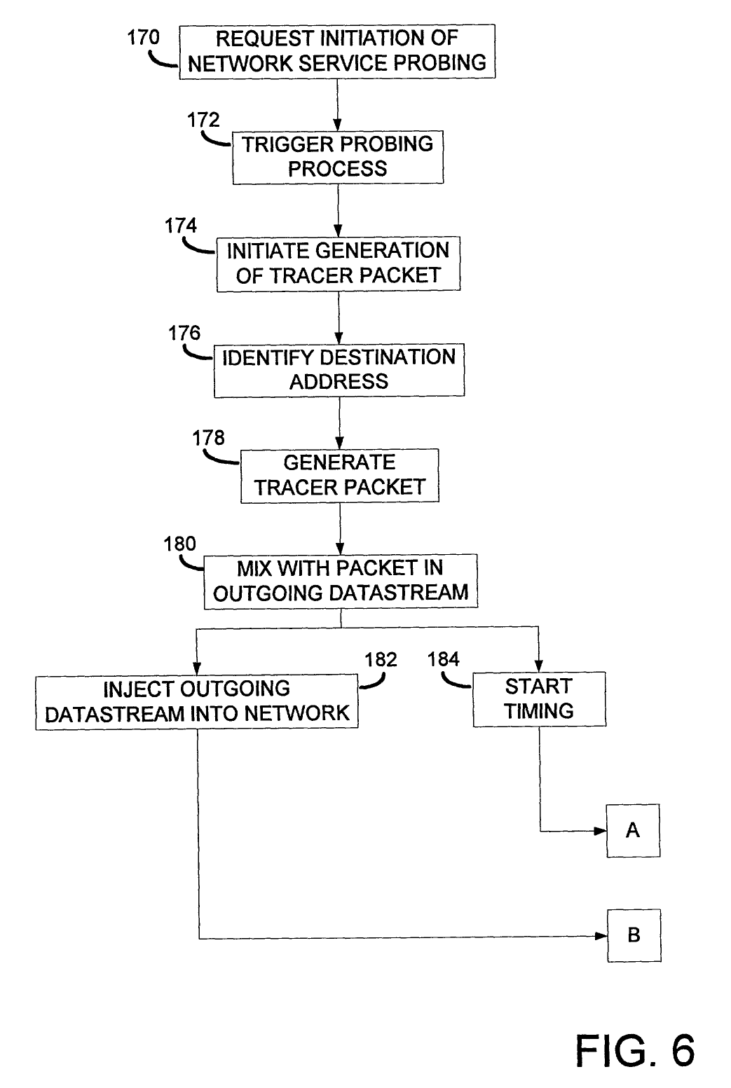

FIG. 6 is a process flow diagram illustrating operation of one embodiment of the end device NMM 30 when network service probing is initiated manually by a user of the end device 18 (FIG. 1). For purposes of explaining operation, assume that the user is, for example, downloading a multimedia file over the network architecture 12 (FIG. 1) when the download becomes extremely slow.

Referring now to FIGS. 1, 3 and 6, at block 170, the user may manually initiate network service probing by, for example, clicking on a “network probe” icon. At block 172, the User Interface component 50 passes the manual request to the probing Trigger component 64 to trigger the probing process. The probing Trigger component 64 sends a request to the packet Generator component 62 to initiate generation of a tracer packet at block 174. At block 176, the packet Generator component 62 calls the traffic Monitoring component 54 to identify the destination address of the destination device to which datastream traffic from the end device 18 is directed.

The packet Generator component 62 utilizes the destination address to produce a tracer packet at block 178. At block 180, the tracer packet is received by the traffic Monitoring component 54 and mixed into the outgoing flow of packets of application data directed to the destination device. The outgoing datastream formed by the outgoing packets of application data along with the outgoing tracer packet is received by the packet Sending component 60, and injected into the first heterogeneous network 14 at block 182. At block 184, the traffic Monitoring component 54 informs the Tracer Timer component 58 to keep track of the outgoing tracer packet departure time.

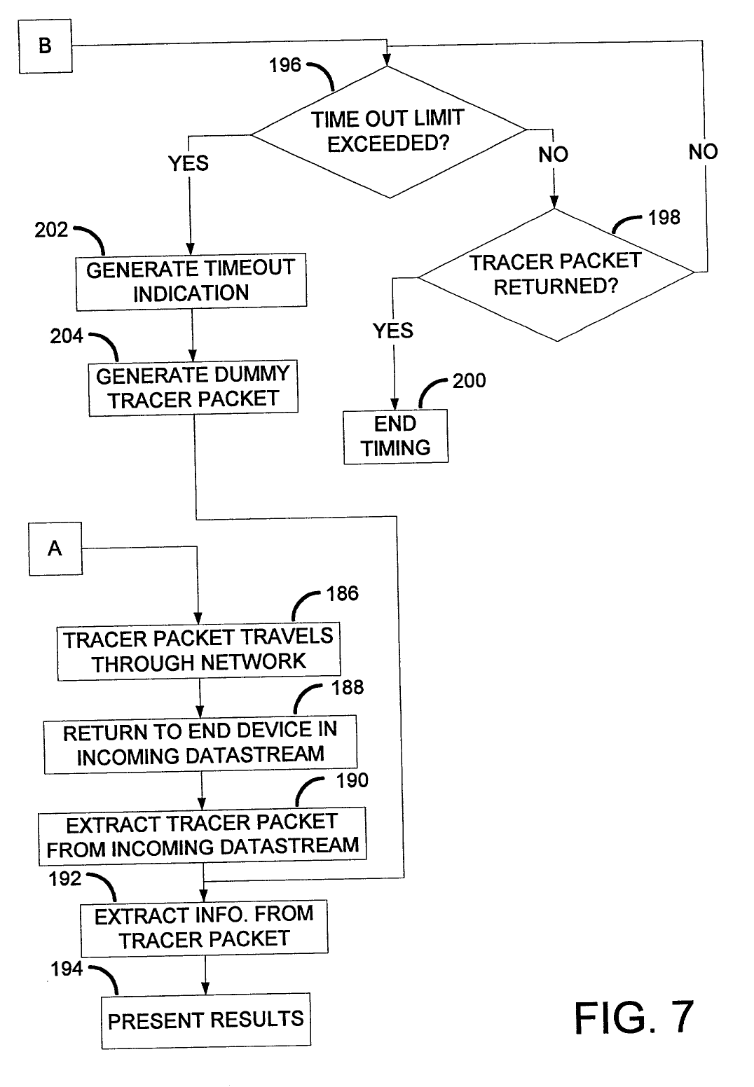

Referring now to FIG. 7, at block 186, the tracer packet travels through the first heterogeneous network 14. The tracer packet eventually returns to the end device 18 as part of an incoming datastream at block 188. At block 190, the packet Sending component 60 receives and passes the incoming datastream to the traffic Monitoring component 54 where the tracer packet is recognized and extracted from the incoming datastream. At block 192, the extracted tracer packet is passed to the packet Decipher component 56 where information carried in the tracer packet is extracted and processed. The results of the processing are passed to the User Interface component 50, which presents the results to the user in graphic or table format at block 194.

During the time the tracer packet is traveling through the first heterogeneous network 14 (block 186), the Tracer Timer component 58 determines if the time since departure of the tracer packet exceeds the time out limit at block 196. If the time out limit has not been exceeded, the Tracer Timer component 58 checks for indication from the traffic Monitoring component 54 that the tracer packet has returned to the end device 18 at block 198. If yes, timing ends at block 200. If there is no indication that the tracer packet has returned, the Tracer Timer component 58 returns to block 196.

If at block 196, the time out limit has been exceeded, the Tracer Timer component 58 generates a timeout indication to the traffic Monitoring component 54 at block 202. At block 204, the traffic Monitoring component 54 relates the timeout indication to the packet Generator component 62, which will then generate a dummy tracer packet with the timeout information. The dummy tracer packet is passed from the traffic Monitoring component 54 to the packet Decipher component 56 and the operation continues at block 192.

Referring again to FIG. 1, upon initiation of network service probing, the outgoing datastream including the tracer packet travels over the first heterogeneous network 14 through at least one intermediate node 20. Typically, the datastream will make several hops between intermediate nodes 20 prior to reaching the gateway 22. As previously discussed, the intermediate nodes 20 are not required to include the intermediate node NMM 32. As a result, no network service information pertaining to intermediate nodes 20 that do not include the intermediate node NMM 32 will be stored in tracer packets traveling therethrough.

The software present on an intermediate node 20 that has been chosen to support the network monitoring system 10 is upgraded to include the intermediate node NMM 32. During operation, the intermediate node NMM 32 monitors and stores network service information. The network service information pertains to the intermediate node 20 on which intermediate node NMM 32 is operating. In addition, the intermediate node NMM 32 may identify and intercept tracer packets within datastreams passing therethrough. The intermediate node NMM 32 may write network service information therein and return the intercepted tracer packets back to the datastream. The tracer packets are otherwise routed through the intermediate node 20 similar to other packets in the datastream. In one embodiment, when a tracer packet travels through an intermediate node 20 multiple times, the intermediate node NMM 32 may write additional network service information into the tracer packet each time. In another embodiment, the intermediate node NMM 32 may update existing network service information each subsequent time the tracer packet passes through the intermediate node 20.

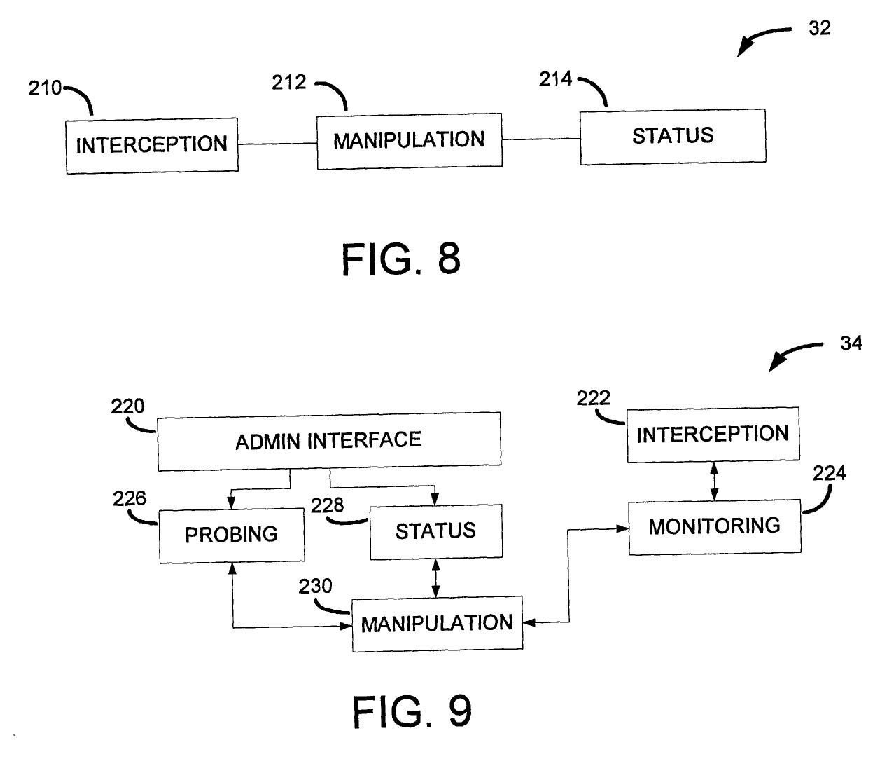

FIG. 8 is a block diagram of one embodiment of the intermediate node NMM 32. The intermediate node NMM 32 includes a packet Interception component (IC) 210, a packet Manipulation component (MC) 212 and a Status component (SC) 214 coupled as illustrated in FIG. 8. In other embodiments, fewer or greater numbers of components may be used to describe the functionality of the intermediate node NMM 32.

The packet Interception component 210 of one embodiment may recognize and intercept tracer packets from the datastream. In one embodiment, packet interception may involve temporarily detaining the recognized tracer packets. In another embodiment, the entire datastream is temporarily detained to process the tracer packet(s) therein.

The packet Manipulation component 212 of one embodiment may process the tracer packets to store network service information. Processing involves writing attributes of the network services information into segments within the HANT data 96 (FIG. 4) of the tracer packet. In addition, the value in the total length field 76 (FIG. 4) may be updated accordingly.

The Status component 214 of one embodiment monitors and maintains the network service information for the intermediate node 20 upon which the intermediate node NMM 32 is operating. Monitoring by the intermediate node NMM 32 may be initiated on a predetermined schedule, by the tracer packet and/or based on the occurrence of predetermined events at the intermediate node 20. Predetermined events may include, for example, network traffic, datastream quality or any other conditions.

Referring once again to FIG. 1, eventually, datastreams destined for other heterogeneous networks travel through the gateway 22. In the illustrated embodiment, the first heterogeneous network 14 is coupled with the core Internet 26 via the gateway 22 as previously discussed. The gateway NMM 34 may filter and intercept tracer packets from datastreams traveling out of the first heterogeneous network 14. In addition, the gateway NMM 34 may probe the application server 24 in the second heterogeneous network 16, and the link thereto, for the quality of remote operating conditions. When probing the quality of the link to the remote application server 24, as well as application server load/congestion information, etc., the gateway 22 may act as a proxy on behalf of the end device 18. Further, network service information for operating conditions around the gateway 22 may also be gathered by the gateway NMM 34. The remote operating conditions and the network service information may be cached by the gateway NMM 34 as network condition information as previously discussed.

Intercepted tracer packets may be processed by the gateway NMM 34. Processing involves storing the network condition information within the HANT data 96 (FIG. 4) of the tracer packets and adjusting the value in the total length field 76 (FIG. 4) accordingly. Following processing, the tracer packets may be returned to the end device 18 by the gateway NMM 34, instead of being forwarded to the destination device.

FIG. 9 is a block diagram illustrating one embodiment of the gateway NMM 34. The gateway NMM 34 includes an Administration Interface component (AIC) 220, a gateway packet Interception component (IC) 222, a gateway packet Monitoring component (MC) 224, a Probing component (PC) 226, a gateway Status component (SC) 228 and a gateway packet Manipulation component (MPC) 230 coupled as illustrated in FIG. 9. In other embodiments additional or fewer components may be utilized to describe the functionality of the gateway NMM 34.

The Administration Interface component 220 may allow an administrator to control, configure and/or monitor the gateway NMM 34. The gateway packet Interception component 222 may monitor the datastream and examine the protocol ID of each packet to identify and intercept tracer packets. Other packets, such as application data packets, may be allowed by the gateway packet Interception component 222 to pass unaffected. Tracer packets, however, may be captured and sent to the gateway packet Monitoring component 224.

The gateway packet Monitoring component 224 may pass the tracer packets to the gateway packet Manipulation component 230. In addition, the gateway packet Monitoring component 224 may receive manipulated tracer packets from the gateway packet Manipulation component 230. Manipulated tracer packets may be injected back into the network architecture 12 through the gateway packet Interception component 222 via the gateway packet Monitoring component 224.

The Probing component 226 may probe a remote application server or other destination device identified by the destination address field 92 (FIG. 4) within the tracer packets. In addition, the Probing component 226 may also cache and/or aggregate probing results in preparation for future tracer packets from end devices 18 that include the same destination address.

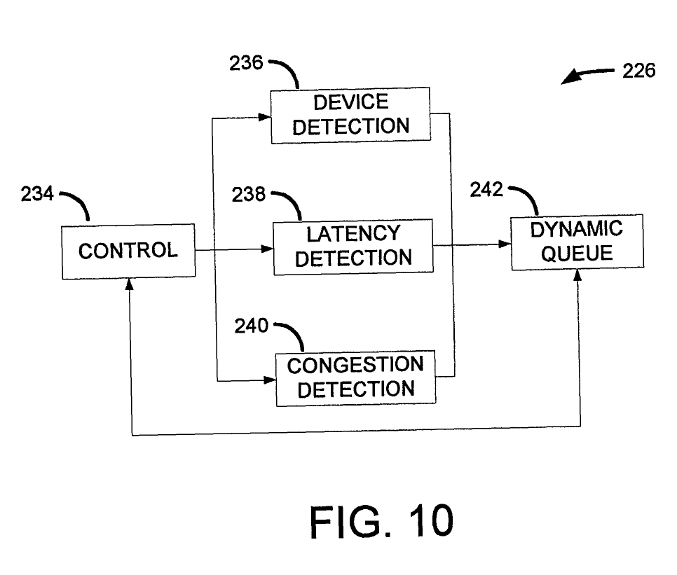

FIG. 10 is a more detailed block diagram of one embodiment of the Probing component 226. The Probing component 226 includes a Control component (CC) 234, a Device Detection component (DC) 236, a Latency Detection component (LDC) 238, a Congestion Detection component (CDC) 240 and a Dynamic Queue component (DQC) 242 couple as illustrated in FIG. 10. In other embodiments, fewer or greater numbers of components may be identified to describe the functionality of the Probing component 226.

The Control component 234 may provide a communication channel between the Probing component 226 and the packet Manipulation Component 230 (FIG. 9). In addition, the Control component 234 may direct and coordinate the other components within the Probing component 226.

The Device Detection component 236 may determine the function of the destination device and the type of device being probed. For example, if the application server 24 (FIG. 1) is being probed, the Device Detection component 236 may identify the function of the device as a server and the type of server as, for example, a request/response type or streaming type server. According to the function and device type detected, the Probing component 226 may probe parameters relevant to the end device 18 accessing the destination device.

The Latency Detection component 238 may detect communication latency between the gateway 22 (FIG. 1) and a destination device, such as, for example, the application server 24 (FIG. 1). Detection of latency may be performed differently depending on the device and the device type identified by the Device Detection component 236. For example, a number of approaches are available for latency detection in an application server of request/response type.

In one embodiment where the destination device is an application server of request/response type, latency detection may be similar to well known trace-routing techniques. In this embodiment, the Latency Detection component 238 may first send an IP packet to the application server. The IP packet may be generated with the time-to-live field set to a predetermined number, such as for example “1.” Accordingly, the packet will be dropped by the router on the path to the application server corresponding to the predetermined number, and an ICMP packet will be generated and sent back to the gateway 22 (FIG. 1). The Latency Detection component 238 may then increase the time-to-live field by 1, and send another IP packet. Repeating this procedure a few times, an IP packet will eventually reach the application server and an ICMP packet may be generated and sent back from the application server. The trip times from the combination of the IP packet and the ICMP packet provide indication of communication path latency. In other embodiments, other techniques may be utilized to detect latency such as, for example, Telnet or other pinging techniques.

The Congestion Detection component 240 may store and analyze information previously obtained with the Probing component 226. Logic within the Congestion Detection component 240 may utilize the information previously gathered to infer further information about the destination device. For example, if the response time from a destination device is much longer than the previously detected transmission latency, the Congestion Detection component 240 may indicate that the destination device is overloaded and provide such information as part of the network condition information supplied to the tracer packets. Similarly, if there is no response from the destination device, the Congestion Detection component 240 may indicate that the destination device is down. Alternatively, the Congestion Detection component 240 may utilize previously gathered information to determine that the network connectivity to the destination device is functional, however the destination device may be overloaded and ignoring further requests. In other embodiments, additional probing functionality may also be included in the Probing component 226 such as, for example, application and/or network level communication with the destination device to exchange destination device and network link information. The application and/or network level communication may involve, for example, simple network management protocol (SNMP) to probe the destination device.

The Dynamic Queue component 242 may provide a queuing function for the Probing component 226. Since multiple destination devices may be probed simultaneously by the Probing component 226, the Dynamic Queue component 242 may dynamically maintain a current listing of destination devices being probed. In addition, probing information gathered by the components of the Probing component 226 may be stored, together with identification of the corresponding destination device, by the Dynamic Queue component 242. The list may be dynamically shortened or lengthened by the Dynamic Queue component 242 as the number of destination devices being probed changes.

During operation, if a new destination device is to be probed, the Control component 234 may direct the Dynamic Queue component 242 to add the destination device to the list. In addition, the Control component 234 may selectively direct the other components of the Probing component 226 to probe the destination device and provide the resulting probing information to the Dynamic Queue component 242 for association with the destination device listing. If a probing request comes in for probing a destination device that has previously been probed, the Control component 234 may direct the Dynamic Queue component 242 to fetch the existing probing information, instead of repeating probing of that destination device. The Control component 234 may also periodically direct the Dynamic Queue component 242 to remove destination devices and associated probing information from the list. Criteria for removal of destination devices may be based on, for example, a predetermined time, volume of probing requests directed to a destination device, significant changes in network operation or any other logic-based mechanism.

Referring again to the embodiment of the gateway NMM 34 illustrated in FIG. 9, the gateway Status component 228 may monitor and maintain network service information with regard to the gateway 22 (FIG. 1). As previously discussed, the network service information may include statistical information regarding operating conditions in and around the gateway 22, such as, for example, congestion and the like.

The gateway packet Manipulation component 230 may store network condition information (probing information and network service information) and otherwise configure tracer packets intercepted by the gateway NMM 34. In the illustrated embodiment, the gateway packet Manipulation component 230 may receive tracer packets from the gateway packet Monitoring component 224. The gateway packet Manipulation component 230 may query the Probing component 226 for probing information based on the destination address included in the tracer packet. In addition, the gateway Status component 228 may be queried for network service information on the gateway 22. The packet Manipulation component 230 may combine and write the information obtained by these queries into the tracer packet to form the network condition information.

The tracer packet may also be configured by the gateway packet Manipulation component 230 for re-direction back to the end device 18 (FIG. 1) over the first heterogeneous network 14 (FIG. 1). In the embodiment discussed with reference to FIG. 4, where the tracer packet includes the source address field 90 and the destination address field 92, the addresses within these fields may be interchanged by the gateway packet Manipulation component 230 so as to “bounce” the tracer packet back to the end device 18 (FIG. 1). After configuration by the gateway packet Manipulation component 230, the tracer packet may be passed back to the gateway packet Monitoring component 224.

In one embodiment, the gateway packet Manipulation component 230 may include a tracer packet queue. The tracer packet queue may allow the gateway packet Manipulation component 230 to process multiple tracer packets at the same time. Accordingly, tracer packets may be queued while the gateway packet Manipulation component 230 awaits probing of destination devices identified by the tracer packets. Queuing the tracer packets enables the gateway packet Manipulation component 230 to simultaneously process tracer packets from one or more end devices 18 (FIG. 1) to obtain probing information from one or more destination devices.

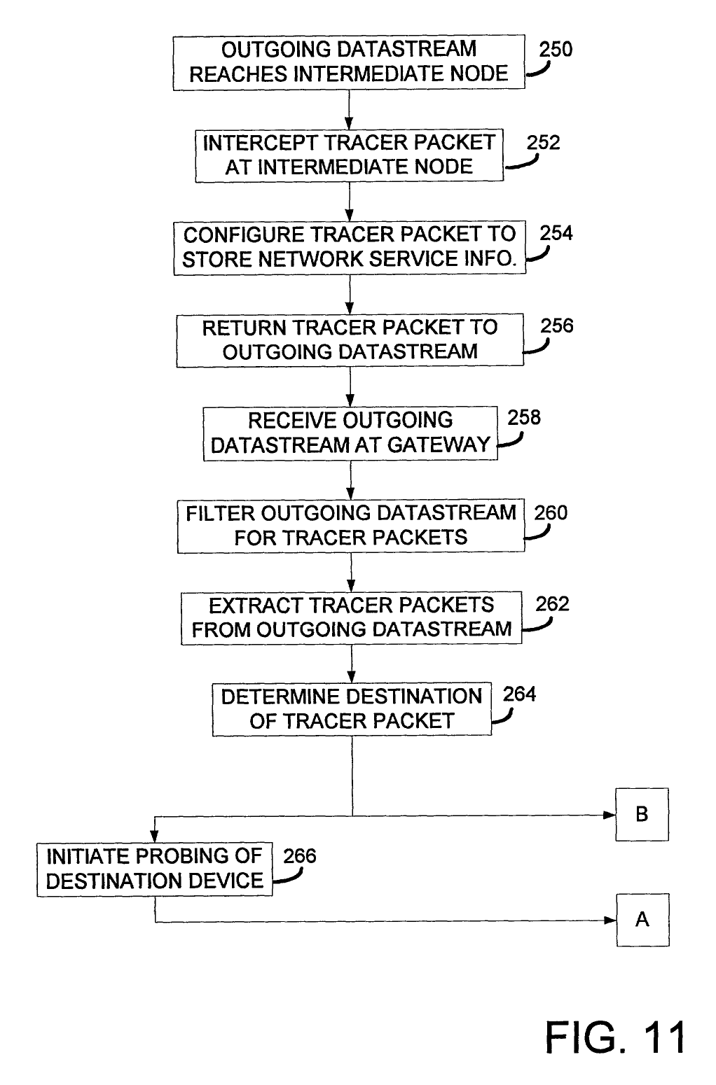

FIG. 11 is a process flow diagram illustrating operation of one embodiment of the network monitoring system 10. Operation is focused on the intermediate node NMM 32 and the gateway NMM 34 previously discussed with reference to FIGS. 8, 9 and 10. Referring now to FIGS. 1, 8, 9, 10 and 11, assume that an outgoing datastream that includes a tracer packet has already been injected into the first heterogeneous network 14 by the end device 18.

Operation begins at block 250 when the outgoing datastream reaches the intermediate node 20. As previously discussed, if the intermediate node 20 does not include the intermediate node NMM 32, the outgoing tracer packet may remain unchanged, and travel through the intermediate node 20 with the outgoing datastream. For purposes of illustrating operation, the intermediate node 20 includes the intermediate node NMM 32. With reference to FIG. 8, at block 252 the packet Interception component 210 recognizes and intercepts the tracer packet based on characteristics, such as, for example, a protocol value included in the tracer packet. The intercepted tracer packet is configured by the packet Manipulation component 212 to store network service information at block 254. As previously discussed, the network service information may be collected by the Status component 214 for later transfer to the tracer packets by the packet Manipulation component 212. Following configuration, at block 256 the tracer packet may be returned to the outgoing datastream by the packet Manipulation component 212 to continue traveling towards the destination device. As previously discussed, the outgoing datastream may travel through any number of intermediate nodes 20 within the first heterogeneous network 14 and additional network service information may be stored therein by intermediate nodes 20 that include the intermediate node NMM 32. Eventually, the outgoing datastream is received by the gateway 22 at block 258.

With reference to FIG. 9, the gateway packet Interception component 222 filters the outgoing datastream and monitors for characteristics in the packets indicative of tracer packets at block 260. At block 262 the identified tracer packets are extracted by the gateway packet Interception component 222 and passed to the gateway packet Monitoring component 224. The gateway packet Monitoring component 224 passes the extracted tracer packet to the gateway packet Manipulation component 230 where the destination is determined from the destination address at block 264. At block 266, the gateway packet Manipulation component 230 provides the destination address from the tracer packet to the Probing component 226 to initiate probing of the identified destination device.

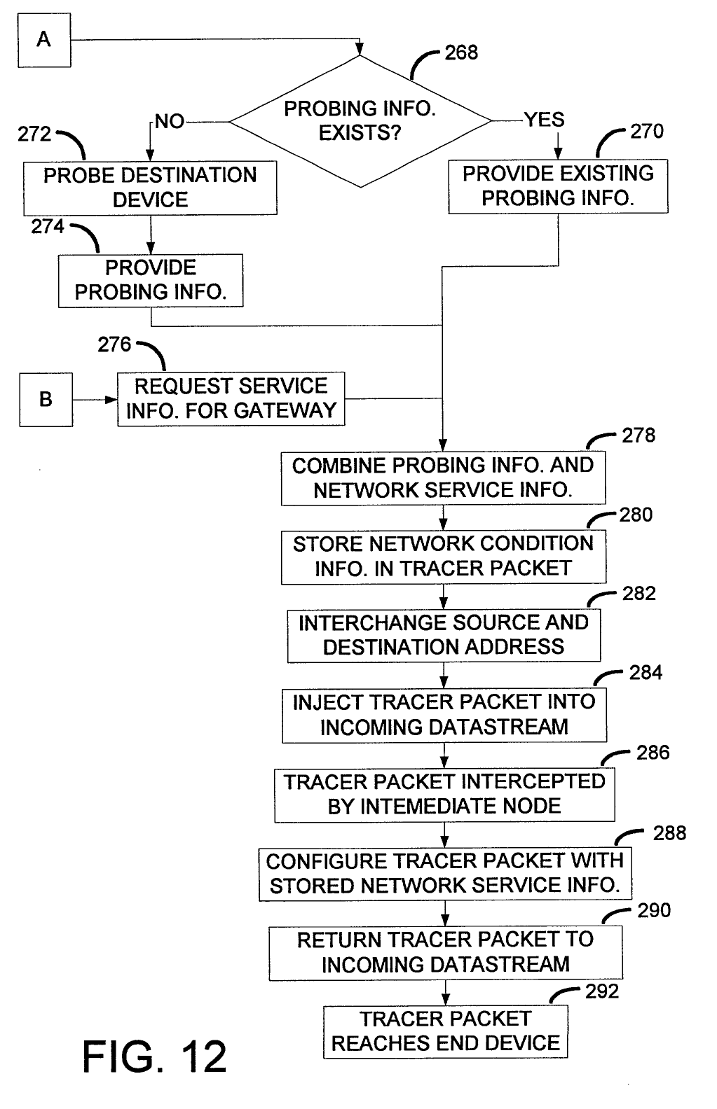

Referring to FIG. 12, with reference to FIGS. 9 and 10, the Control component 234 (within the Probing component 226) accesses the Dynamic Queue component 242 to determine if probing information exists for the destination device at block 268. If yes, the previously gathered probing information is fetched and provided to the gateway packet Manipulation component 230 at block 270. If no probing information exists, the Control component 234 initiates probing by at least one of the Device Detection component 236, the Latency Detection component 238 and the Congestion Detection component 240 at block 272. At block 274, the probing information is provided to the gateway packet Manipulation component 230 and the Dynamic Queue component 242.

With reference again to FIGS. 1 and 9, in addition to initiating the probing of the destination device, the gateway packet Manipulation component 230 also queries the gateway Status component 228 for network service information regarding the gateway 22 at block 276. At block 278 the gateway packet Manipulation component 230 combines the probing information and the network service information to form network condition information. The network condition information is written into the tracer packet by the gateway packet Manipulation component 230 at block 280. At block 282, the gateway packet Manipulation component 230 interchanges the destination address and the source address of the tracer packet.

The tracer packet is passed to the gateway packet Interception component 222 via the gateway packet Monitoring component 224 and injected into an incoming datastream to the end device 18 at block 284. At block 286 the incoming datastream travels through an intermediate node 20 that includes the intermediate node NMM 32 and the packet Interception component 210 intercepts the tracer packet. The intercepted tracer packet is further configured with network service information by the packet Manipulation component 212 in cooperation with the Status component 214 at block 288. At block 290, the tracer packet is returned to the incoming datastream and blocks 286, 288 and 290 are repeated at each intermediate node 20 that includes an intermediate node NMM 32 until the tracer packet reaches the end device 18 at block 292.

The previously discussed embodiments of the network monitoring system 10 provides for network probing of the network architecture 12 by a user of an end device 18. Network probing provides network operating conditions both for the access network of the end device 18 as well as operating conditions related to the destination device(s) the end device 18 is communicating with over the network architecture 12. The user may utilize the end device 18 to display the results of network probing as well as initiate network probing when a problem is perceived.

Network probing may be selectively performed within the access network of the end device 18 based on the communication path of incoming and outgoing datastreams of the end device 18. In addition, network probing may be based on selective deployment of intermediate node NMM's 32 on the intermediate nodes 20 within the access network. Increased network traffic resulting from the network probing is minimal since tracer packets may be selectively generated only when needed, and only a few tracer packets may be needed to obtain network-probing results. Although tracer packets may only be sent intermittently, the network monitoring system 10 may continuously maintain ongoing network operating conditions and statistics due to the network performance information gathered at the intermediate node and gateway NMMs 32, 34.

The network monitoring system 10 may also provide flexibility in the information provided since the network monitoring modules may gather information from any layer of the OSI model. In addition, the network monitoring system 10 is relatively quick and easy to deploy since an end device NMM 30 operating on an end device 18 and a gateway NMM 34 operating on each gateway 22 allows the system to provide network service probing results to a user operating the end device 18. Further, flexible data storage within the tracer packets maintains the stability of the datastream transport system of the network architecture 12 without regard to the magnitude, format or content of the information gathered and carried by the tracer packets.

While the present invention has been described with reference to specific exemplary embodiments, it will be evident that various modifications and changes may be made to these embodiments without departing from the broader spirit and scope of the invention as set forth in the claims. Accordingly, the specification and drawings are to be regarded in an illustrative rather than a restrictive sense.

What is claimed is:

1. A method of monitoring network performance with an end device communicating over interconnected heterogeneous networks, the method comprising:
a) generating a datastream in a heterogeneous network with an end device, the datastream comprising a tracer packet;
b) collecting network service information from at least one intermediate node within the heterogeneous network with the tracer packet;
c) returning the tracer packet over the heterogeneous network to the end device; and
d) interpreting the network service information in the tracer packet.

2. The method of claim 1, wherein a) comprises generating the tracer packet with a format substantially similar to an application data Internet protocol (IP) packet with the addition of heterogeneous access network tracking (HANT) data.

3. The method of claim 2, wherein heterogeneous access network tracking (HANT) data comprises at least one of a node-type field, a node-ID field, an attribute name field, an attribute value field, an attribute type field and a timestamp field.

4. The method of claim 2, wherein generating the tracer packet comprises filling a protocol field of the tracer packet with a heterogeneous access network tracking (HANT) protocol.

5. The method of claim 1, wherein a) comprises generating the tracer packet as a function of at least one of an automatic probe mode, a manual probe mode and an event probe mode.

6. The method of claim 1, wherein b) comprises:
extracting the tracer packet from the datastream;
storing network traffic conditions present at the at least one intermediate node in the tracer packet; and
returning the tracer packet to the datastream.

7. The method of claim 1, wherein b) comprises identifying the network service information associated with the at least one intermediate node.

8. The method of claim 1, wherein the datastream comprises a plurality of packets and b) comprises routing the tracer packet as one of the packets.

9. The method of claim 1, wherein b) comprises selectively configuring the at least one intermediate node to recognize the tracer packet, wherein the tracer packet is unrecognizable by intermediate nodes that remain unconfigured.

10. The method of claim 1, wherein c) comprises:
extracting the tracer packet from the datastream;
writing network condition information into the tracer packet; and
re-routing the tracer packet to return to the end device.

11. The method of claim 1, wherein d) comprises:
deciphering the network service information; and
presenting results on the end device.

12. A method of monitoring network performance with an end device communicating over interconnected heterogeneous networks, the method comprising:
a) filtering a datastream passing from a first heterogeneous network to a second heterogeneous network to identify a tracer packet;
b) probing a destination device operating in the second heterogeneous network for probing information as a function of the tracer packet;
c) storing the probing information as network condition information in the tracer packet; and
d) routing the tracer packet to an end device in the first heterogeneous network.

13. The method of claim 12, wherein a) comprises:
extracting the tracer packet from the datastream; and
leaving the remainder of the datastream intact.

14. The method of claim 12, wherein b) comprises detecting at least one of; the function of the destination device, the type of destination device, the communication latency to the destination device and congestion around the destination device.

15. The method of claim 12, wherein b) comprises storing the probing information for use in another tracer packet.

16. The method of claim 12, wherein c) comprises
storing network service information in the tracer packet as part of the network condition information.

17. The method of claim 12, wherein c) comprises:
adding a segment to the tracer packet; and
adjusting the value of a total length field in the tracer packet as a function of the added segment.

18. The method of claim 12, wherein c) comprises:
modifying the length of a variable length data segment in the tracer packet; and
adjusting the value of a total length field in the tracer packet as a function of the modified length.

19. The method of claim 12, wherein d) comprises exchanging a source address and a destination address in the tracer packet.

20. The method of claim 12, wherein the first heterogeneous network and the second heterogeneous network are interconnected and communicate over the core Internet.

21. A method of monitoring network performance, with an end device communicating over interconnected heterogeneous networks, the method comprising:
a) generating a datastream with an end device, the datastream comprising a plurality of data packets and a tracer packet each comprising a destination address of an application server;
b) routing the datastream over a heterogeneous network through an intermediate node;
c) selectively storing network service information in the tracer packet at the intermediate node;
d) removing the tracer packet from the datastream at a gateway;
e) gathering network condition information at the gateway as a function of the destination address of the tracer packet;
f) storing the network condition information in the tracer packet; and
g) routing the tracer packet back over the heterogeneous network through the intermediate node to the end device.

22. The method of claim 21, wherein a) comprises generating the tracer packet with a protocol identification different from the other data packets.

23. The method of claim 22, wherein b) and d) comprise identifying the tracer packet in the datastream as a function of the protocol identification.

24. The method of claim 21, wherein a) comprises tracking the time of departure of the tracer packet from the end device, wherein loss of the tracer packet is determined as a function of the time of departure.

25. The method of claim 21, wherein c) comprises writing network traffic conditions around the intermediate node into the tracer packet.

26. The method of claim 21, wherein e) comprises at least one of:
determining the function and type of the application server;
detecting communication latency between the gateway and the application server; and
detecting congestion at the application server.

27. The method of claim 21, wherein f) comprises:
storing the network condition information in the gateway; and
reusing the network condition information for future tracer packets directed to the same application server.

28. A network monitoring system for monitoring network performance with an end device communicating over heterogeneous networks, the network monitoring system comprising:
a network comprising a first heterogeneous network communicatively coupled with a second heterogeneous network;
an end device operable in the first heterogeneous network;
an application server operable in the second heterogeneous network, the end device and the application server operable to communicate over the network with a datastream, the end device operable to generate a tracer packet as part of the datastream; and
a gateway operable in the first heterogeneous network as an interface to the second heterogeneous network, the gateway operable to store network condition information in the tracer packet and redirect the tracer packet back to the end device over the first heterogeneous network.

29. The network monitoring system of claim 28, further comprising an intermediate node operable in the first heterogeneous network, the datastream operable to travel through the intermediate node, the intermediate node operable to store network service information in the tracer packet.

30. The network monitoring system of claim 28, wherein the end device comprises one of a wireless phone, a personal digital assistant (PDA) and a laptop computer.

31. The network monitoring system of claim 28, wherein the first heterogeneous network comprises a wireless network and the second heterogeneous network comprises a wireline network.

32. The network monitoring system of claim 28, wherein the first heterogeneous network is communicatively coupled with the second heterogeneous network via the core Internet.

33. The network monitoring system of claim 28, wherein the tracer packet comprises a source address, a destination address, a protocol field and heterogeneous access network tracking (HANT) data, the size of the heterogeneous access network tracking (HANT) data adjustable to accommodate variable amounts of data provided by the gateway.

34. The network monitoring system of claim 33, wherein the heterogeneous access network tracking (HANT) data comprises at least one of a node-type field, a node-ID field, an attribute name field, an attribute value field, an attribute type field and a timestamp field.

35. The network monitoring system of claim 28, wherein the end device comprises: a user interface component, an end device packet interception component, a traffic monitoring component, a packet decipher component, a tracer timer component, a packet sending component, a packet generator component, a probing trigger component and an event generator component.

36. The network monitoring system of claim 29, wherein the intermediate node comprises: a packet interception component, a packet manipulation component and a status component, the status component operable to store and maintain statistical information related to the intermediate node.

37. The network monitoring system of claim 28, wherein the gateway comprises: an administration interface component, a gateway packet interception component, a gateway packet monitoring component, a probing component, a gateway status component and a gateway packet manipulation component.

38. The network monitoring system of claim 28, wherein the end device comprises an end device network monitoring module, the end device network monitoring module operable in a network stack between a transport layer and a network layer.
